(19) United States
(12) Patent Application Publication
(10) Pub. No.: US 2024/0282895 A1
(43) Pub. Date: Aug. 22, 2024

(54) LIGHT FIELD DISPLAY

(71) Applicant: SAMSUNG ELECTRONICS CO, LTD., Suwon-si (KR)

(72) Inventors: Shunsuke KIMURA, Suwon-si (KR); Jaeseok KIM, Suwon-si (KR); Kilsoo JUNG, Suwon-si (KR); Seungryong HAN, Suwon-si (KR)

(73) Assignee: SAMSUNG ELECTRONICS CO, LTD., Suwon-si (KR)

(21) Appl. No.: 18/649,591

(22) Filed: Apr. 29, 2024

Related U.S. Application Data
(63) Continuation of application No. PCT/KR2022/020474, filed on Dec. 15, 2022.

(30) Foreign Application Priority Data
Dec. 21, 2021 (KR) 10-2021-0183855

(51) Int. Cl. H01L 33/58; G02B 30/10; H01L 25/075

(52) U.S. Cl. CPC H01L 33/58; G02B 30/10; H01L 25/0753

(57) ABSTRACT

A light field device including: a plurality of microdisplays; a plurality of first lenses on the plurality of microdisplays and configured to refract light output from the plurality of microdisplays; and a plurality of second lenses on the plurality of first lenses and configured to refract light that is projected from the plurality of first lenses, wherein each of the plurality of microdisplays includes a light emitting region including a plurality of micro-LEDs and a bezel region surrounding the light emitting region, and a pitch of the plurality of second lenses is greater than a pitch of the plurality of first lenses.

### CROSS REFERENCE TO RELATED APPLICATION(S)

This application is a continuation of International Application No. PCT/KR2022/020474, filed on Dec. 15, 2022, in the Korean Intellectual Property Receiving Office, which is based on and claims priority to Korean Patent Application No. 10-2021-0183855, filed on Dec. 21, 2021, in the Korean Intellectual Property Office, the disclosures of which are incorporated by reference herein in their entireties.

### BACKGROUND

### 1. Field

The disclosure relates to a light field display, and more particularly, to a light field display including a microdisplay.

### 2. Description of Related Art

With the development of electronic technology, various types of electronic devices have been developed and popularized. In particular, display devices such as televisions, which are one of the most popular household appliances, have been developing rapidly in recent years.

As the performance of display devices has become more advanced, the types of content that can be displayed on display devices have also increased. In particular, stereoscopic display systems capable of viewing three-dimensional (3D) content have been developed and popularized in recent years.

Stereoscopic display systems can be broadly categorized into glasses-free systems, which can be viewed without glasses, and glasses systems, which must be viewed with glasses.

While glasses-based systems can provide a satisfactory stereoscopic experience, they are inconvenient because they require the viewer to wear glasses. In contrast, glasses-free systems have the advantage of being able to view 3D images without glasses, and there are continuous discussions on developing glasses-free systems.

With existing glasses-free systems, a plurality of light field images captured from different viewpoints can be displayed on a light field display to provide a stereoscopic view.

However, the spatial resolution required for light field displays is very high compared to conventional displays, and the possibility of utilizing light field displays using microdisplays with high spatial resolution is increasing.

However, considering the process of conventional microdisplays, a bezel region is required outside the light emitting region including a plurality of micro light-emitting diodes (LEDs). Therefore, in order to realize a large-scale light field display using a plurality of microdisplays, there is a need for a technology in which the bezel region does not affect the 3D image.

### SUMMARY

Provided is a light field display including a plurality of lenses to reduce the impact of a bezel region of a plurality of microdisplays.

Additional aspects will be set forth in part in the description which follows and, in part, will be apparent from the description, or may be learned by practice of the presented embodiments.

According to an aspect of the disclosure, a light field device may include: a plurality of microdisplays; a plurality of first lenses on the plurality of microdisplays and configured to refract light output from the plurality of microdisplays; and a plurality of second lenses on the plurality of first lenses and configured to refract light projected from the plurality of first lenses, where each of the plurality of microdisplays includes a light emitting region including a plurality of micro-LEDs and a bezel region surrounding the light emitting region, and where a pitch of the plurality of second lenses is greater than a pitch of the plurality of first lenses.

The pitch of the plurality of second lenses may be equal to a size of one of the plurality of second lenses, where a size of one of the plurality of microdisplays is equal to the size of the one of the plurality of second lenses.

A convex side of the plurality of first lenses may face the plurality of microdisplays, where a plurality of optical apertures are on a side opposite to the convex side of the plurality of first lenses.

An area in which the plurality of optical apertures overlap each of the plurality of first lenses is based on a preset ratio of a size of the plurality of first lenses, and the preset ratio is 30%.

Each of the plurality of first lenses may include a Grin lens with refractive index distribution.

A first microdisplay among the plurality of microdisplays may correspond to a number of first lenses among the plurality of first lenses, where the number of first lenses corresponds to a second lens among the plurality of second lenses.

One first lens among the number of first lenses may correspond to a plurality of first micro-LEDs in the first microdisplay and may be configured to refract light output from the plurality of first micro-LEDs in the first microdisplay, where the second lens is configured to refract the light refracted by the one first lens among the number of first lenses.

The second lens may have a size greater than a size of one first lens among the number of first lenses.

A distance between the plurality of first lenses and the plurality of second lenses may be based on a quantity of first lenses included in the number of first lenses.

The light field device may further include a resin between the plurality of first lenses and the plurality of second lenses.

The light field device may further include a glass between the plurality of first lenses and the plurality of second lenses.

A ratio of a focal length of the plurality of first lenses and a focal length of the plurality of second lenses may be within a preset range ratio, where the preset range ratio is from 20 to 200.

The plurality of second lenses is configured to refract the light output from the plurality of microdisplays and provide a stereoscopic image.

According to an aspect of the disclosure, a light field display device may include: a light field display; a memory including at least one instruction; and a processor connected to the memory and configured to control the light field display by executing the at least one instruction, where the light field display includes: a plurality of microdisplays; a plurality of first lenses on the plurality of microdisplays and configured to refract light output from the plurality of microdisplays; and a plurality of second lenses on the plurality of first lenses and configured to refract light that is projected from the plurality of first lenses, where each of the plurality of microdisplays includes a light emitting region including a plurality of micro-LEDs and a bezel region surrounding the light emitting region, and where a pitch of the plurality of second lenses is greater than a pitch of the plurality of first lenses.

### BRIEF DESCRIPTION OF DRAWINGS

The above and/or other aspects, features, and advantages of embodiments of the present disclosure will become more apparent and more readily appreciated from the following taken in conjunction with the accompanying drawings, in which:

FIG. 1 is a view illustrating a light field display according to an embodiment;

FIG. 2 is a view illustrating an arrangement of a plurality of microdisplays according to an embodiment;

FIG. 3 is a view provided to explain an embodiment of magnifying an image using a single lens;

FIG. 4 is a view illustrating an embodiment of magnifying light using a two lens configuration according to an embodiment;

FIG. 5 is a view illustrating a light field display according to an embodiment;

FIG. 6A is a view illustrating a path of light output from a micro-LED disposed on a side opposite to an optical axis of a plurality of second lenses from among a plurality of micro-LEDs according to an embodiment;

FIG. 6B is a view illustrating a path of light output from a micro-LED disposed on a left side of a side opposite to an optical axis of a plurality of second lenses from among a plurality of micro-LEDs according to an embodiment;

FIG. 6C is a view illustrating a path of light output from a micro-LED disposed on a right side of a side opposite to an optical axis of a plurality of second lenses from among a plurality of micro-LEDs according to an embodiment;

FIG. 7A is a view illustrating a path of light output from a micro-LED disposed on a right side of an optical axis of a plurality of second lenses from among a plurality of micro-LEDs according to an embodiment;

FIG. 7B is a view illustrating a path of light output from a micro-LED disposed on a right side of an optical axis of a plurality of second lenses from among a plurality of micro-LEDs according to an embodiment;

FIG. 8 is a view illustrating an embodiment in which a plurality of first lenses 110 include an optical aperture according to an embodiment;

FIG. 9A is a view illustrating a case in which a plurality of first lenses are implemented as Grin lenses according to an embodiment;

FIG. 9B is a view illustrating a refractive index of FIG. 9A according to an embodiment;

FIG. 10 is a view illustrating a case in which one of a resin or a glass is disposed between a plurality of first lenses and a plurality of second lenses according to an embodiment; and

FIG. 11 is a block diagram illustrating a light field display device including a light field display according to an embodiment.

### DETAILED DESCRIPTION

Hereinafter, various embodiments of the present disclosure will be described with reference to the accompanying drawings. However, this is not intended to limit the technology described in this disclosure to specific embodiments, and should be understood to include various modifications, equivalents, and/or alternatives to the embodiments of this disclosure. In connection with the description of the drawings, similar reference numbers may be used for similar components and redundant descriptions thereof will be omitted. Additionally, to aid understanding of the disclosure, the attached drawings are not drawn based on actual scale, and the dimensions of some components may be exaggerated.

Additionally, expressions such as “first,” “second,” and the like used in the present disclosure may modify various components regardless of order and/or importance, and may be used only to distinguish one component to another component without limit the corresponding components. For example, a first user device and a second user device may indicate different user devices regardless of order or importance. For example, a first component may be referred to a second component without departing from the scope of rights set forth in the present disclosure, and similarly, the second component may also be referred to as the first component.

The terms used in the present disclosure are merely used to describe specific embodiments and may not be intended to limit the scope of other embodiments. Singular expressions may include plural expressions, unless the context clearly indicates otherwise. Terms used herein, including technical or scientific terms, may have the same meaning as generally understood by a person of ordinary skill in the technical field described in this disclosure. Among the terms used in this disclosure, terms defined in general dictionaries may be interpreted to have the same or similar meaning as the meaning they have in the context of related technology, and unless clearly defined in this disclosure, they are not to be interpreted in an idealistic or overly formal sense. In some cases, even terms defined in the present disclosure cannot be interpreted to exclude embodiments of the present disclosure.

The embodiments described in the present disclosure and the configurations shown in the drawings are merely examples of the embodiments of the present disclosure, and may be modified in various ways to replace the embodiments and drawings of the present disclosure. The present disclosure will be more fully described below with reference to the accompanying drawings, in which like reference numerals refer to like elements.

In the disclosure, the expressions “has,” “have,” “may have,” “comprise,” “may comprise,” “include,” “may include,” “consist of,” or “may consist of” used herein indicate existence of corresponding features (e.g., elements such as numeric values, functions, operations, or components) but do not exclude presence of additional features.

This disclosure uses the term “opposite” to denote traditional opposition in position or direction, and to denote corresponding elements such as where elements are analogous in position or direction.

The present disclosure will be described in more detail below with reference to the drawings.

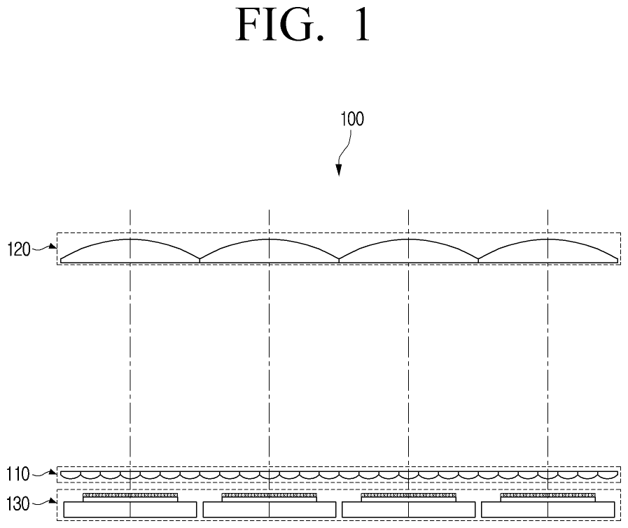

FIG. 1 is a view illustrating a light field display according to an embodiment.

Referring to FIG. 1, a light field display 100 according to an embodiment may include a plurality of first lenses 110, a plurality of second lenses 120, and a plurality of microdisplays 130. In addition, referring to FIG. 1, the plurality of first lenses 110 may be disposed on the plurality of microdisplays 130, and the plurality of second lenses 120 may be disposed on the plurality of first lenses 110.

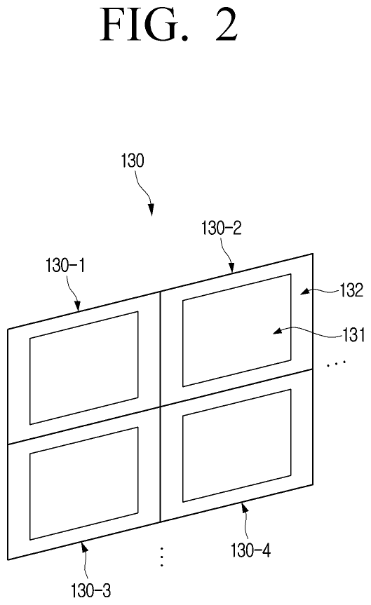

The plurality of microdisplays 130 according to an embodiment may include a plurality of microdisplays. For example, referring to FIG. 2, each of microdisplays 130-1, 130-2, 130-3, and 130-4 may include of an emitting region 131 including a plurality of micro light emitting diodes (LEDs) and a bezel region 132 surrounding the emitting region. FIG. 2 is a view illustrating an arrangement of a plurality of microdisplays according to an embodiment. Referring to FIG. 2, the plurality of microdisplays 130 may be configuration in which each of the microdisplays 130-1, 130-2, 130-3, and 130-4 is modularly combined.

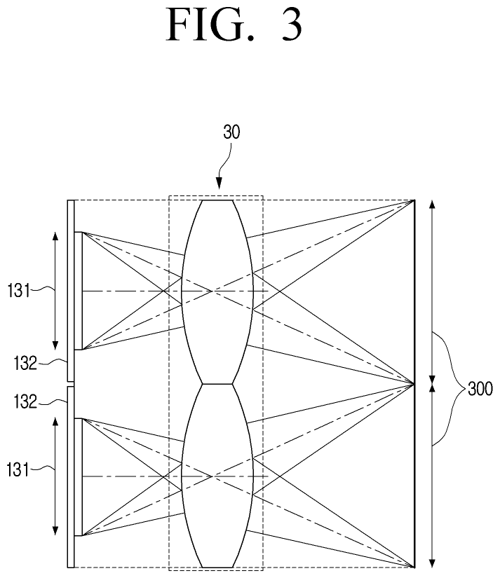

According to the configuration shown in FIG. 2, there is a need for configuration in which the bezel region 132 does not affect the 3D image provided by the plurality of microdisplays 130. Accordingly, it is contemplated to utilize configuration of a single lens 30, as shown in FIG. 3, to magnify the light output from the light emitting region 131 to an enlargement region 300, which includes the bezel region 132. FIG. 3 is a view provided to explain an embodiment of magnifying an image using a single lens. However, when utilizing the configuration of the single lens 300 of FIG. 3, the image is simply magnified by the single lens 30, which may result in deterioration of resolution.

Accordingly, through the configuration of the plurality of first lenses 110 and the plurality of second lenses 120 as shown in FIG. 1, the light output from the light-emitting region 131 can be directed to an enlarged region including the bezel region 132 so that the bezel region 132 does not affect the 3D image provided by the plurality of microdisplays 130 without deterioration of resolution. In other words, according to an embodiment, the light output from the plurality of microdisplays 130 may be refracted by the plurality of second lenses 120 to provide a stereoscopic image without deterioration of resolution.

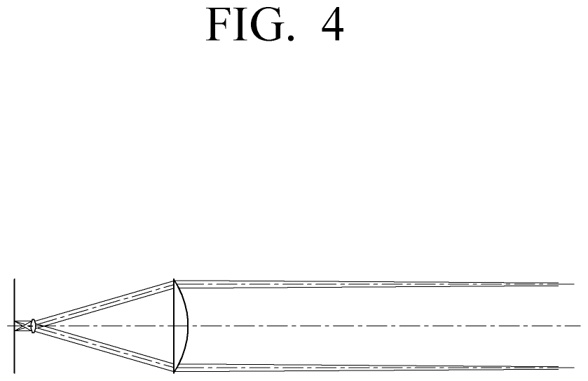

FIG. 4 is a view illustrating an embodiment of magnifying light using a two lens configuration according to an embodiment. In other words, when utilizing the two lens configuration as shown in FIG. 4, rather than magnifying the image, the light output from the plurality of microdisplays 130 may itself be magnified so that the bezel region 132 does not affect the 3D image provided by the plurality of microdisplays 130 without deterioration of resolution.

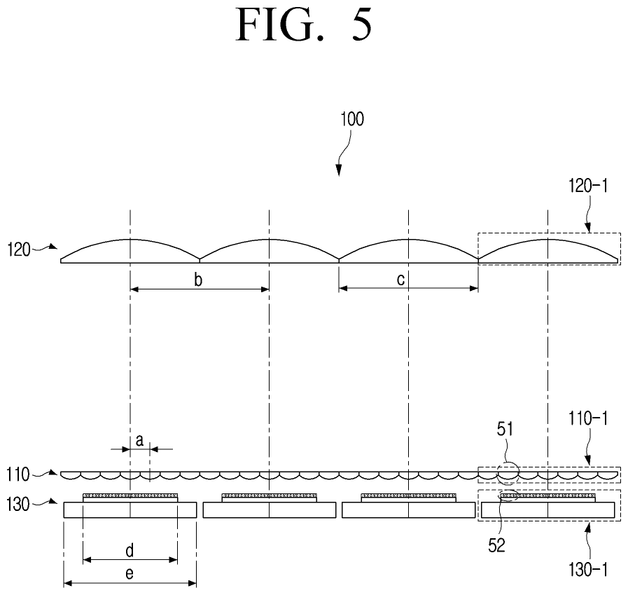

FIG. 5 is a view illustrating a light field display according to an embodiment.

Referring to FIG. 5, each of the microdisplays may be modularly arranged to form the plurality of microdisplays 130. Here, a size (d) of the light emitting region of one of the plurality of microdisplays 130 may be smaller than a size (e) of one of the plurality of microdisplays 130.

Referring to FIG. 5, the plurality of first lenses 110 may be disposed on the plurality of microdisplays 130. In one example, the plurality of first lenses 110 may be implemented as a plurality of lens arrays or a plurality of Grin lenses, but are not limited thereto. The plurality of first lenses 110 may be implemented as various lenses (e.g., lenticular lenses).

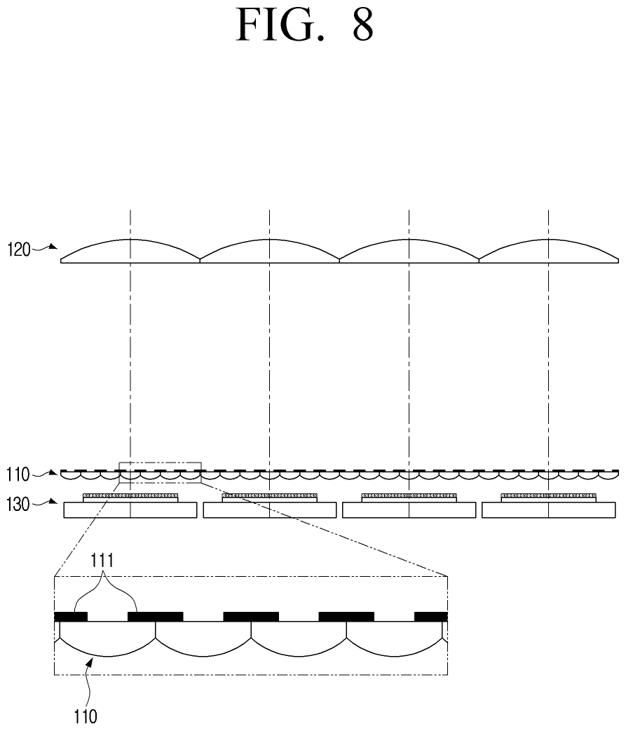

In addition, a convex side of each of the plurality of first lenses 110 may be disposed on a side facing the plurality of microdisplays 130. Further, an optical aperture may be disposed on the opposite side of the convex side of the plurality of first lenses 110, which will be described later with reference to FIG. 8.

A plurality of first lenses may be disposed on a microdisplay of one of the plurality of microdisplays 130. For example, referring to FIG. 5, a first microdisplay 130-1 of the plurality of microdisplays 130 may be disposed on a side opposite to the plurality of first-1 lenses 110-1. Accordingly, a size (a) of a pitch of one of the plurality of first lenses 110 may be smaller than a size (d) of the light emitting region 131 of the microdisplay of one of the plurality of microdisplays 130.

Referring to FIG. 5, the plurality of second lenses 120 may be disposed on the plurality of first lenses 110. In one example, the plurality of first lenses 110 may be implemented as a plurality of lens arrays, but are not limited thereto. The plurality of first lenses 110 may include a variety of lenses (e.g., lenticular lenses).

One second lens may be disposed on a side opposite to a microdisplay of one of the plurality of microdisplays 130. Referring to FIG. 5, one second-1 lens 120-1 may be disposed on a side opposite to the first microdisplay 130-1 and the number of first lenses 110-1. In one example, a pitch size (b) of the plurality of second lenses 120 and a size (c) of one of the plurality of second lenses 120 may be the same. In one example, a size (a) of a pitch of the plurality of first lenses 110 may be smaller than a size (b) of a pitch of the plurality of second lenses 120. Also, in one example, a size (e) of one microdisplay may be equal to a size (c) of one of the plurality of second lenses 120.

The light output from a plurality of first micro LEDs 52 in the first micro display 130-1 disposed on a side opposite to one 51 of the number of first lenses 110-1 may be incident on the one 51 of the number of first lenses 110-1 and refracted by the one 51 of the number of first lenses 110-1. In addition, the light refracted by the one 51 of the number of first lenses 110-1 may be incident on the second-1 lens 120-1 and refracted by the second-1 lens 120-1.

According to an embodiment, a distance between the plurality of first lenses 110 and the plurality of second lenses 120 may be determined by a quantity of the number of first lenses 110-1 disposed on a side opposite to the first microdisplay 130-1.

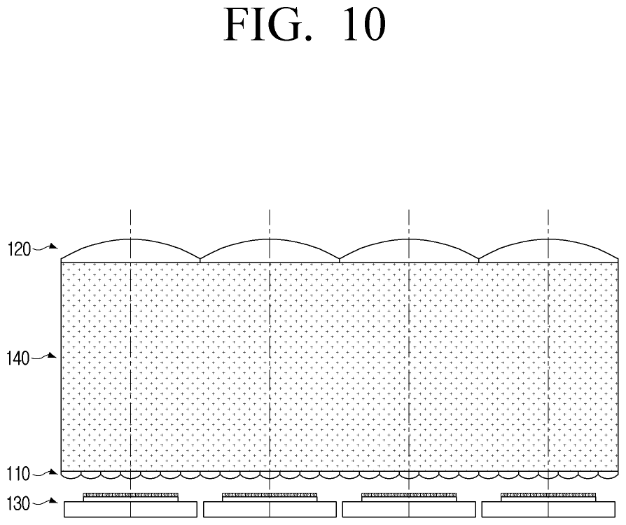

According to an embodiment, one of a resin or a glass may be disposed between the plurality of first lenses 110 and the plurality of second lenses 120, which will be described later with reference to FIG. 10.

According to an embodiment, a ratio (f2/f1) of a focal length (f1) of the plurality of first lenses 110 and a focal length (f2) of the plurality of second lenses may be a preset range ratio. In one example, the preset range ratio may be between 20 and 200. In one example, if the ratio (f2/f1) of the focal length (f1) of the plurality of first lenses 110 and the focal length (f2) of the plurality of second lenses is higher than the upper limit of the preset range, the spatial resolution may be deteriorated, resulting in a deteriorated resolution of the light field display. In one example, if the ratio (f2/f1) of the focal length (f1) of the plurality of first lenses 110 and the focal length (f2) of the plurality of second lenses is lower than the lower limit of the preset range, the angular resolution may be deteriorated, resulting in a deteriorated viewing angle of the light field display.

According to an embodiment, each of the plurality of microdisplays 130 may include a glass, a circuit layer formed on one side of the glass. The circuit layer may include a plurality of pixel circuits for driving a plurality of micro-LEDs constituting each of a plurality of pixels of the plurality of microdisplays 130, and a plurality of drive circuits connected to a driving unit formed on the other side of the glass through wiring formed across the side of the glass and providing drive signals to the plurality of pixel circuits based on signals received from the driving unit. Further, the plurality of drive circuits may be connected to a driving unit on a rear surface of the glass. Here, the driving unit may be configured to control the operation of the plurality of drive circuits based on image data, clock signals, and the like.

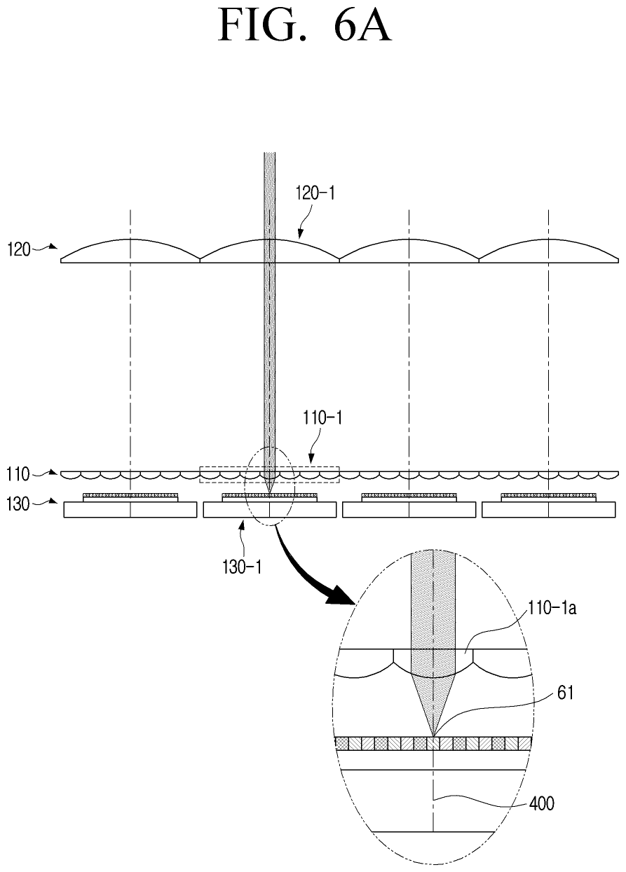

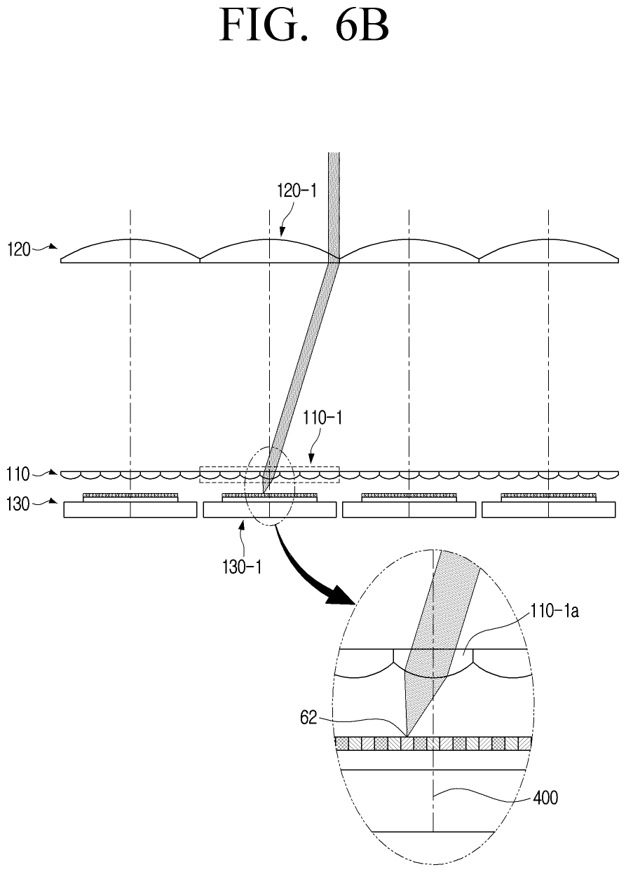

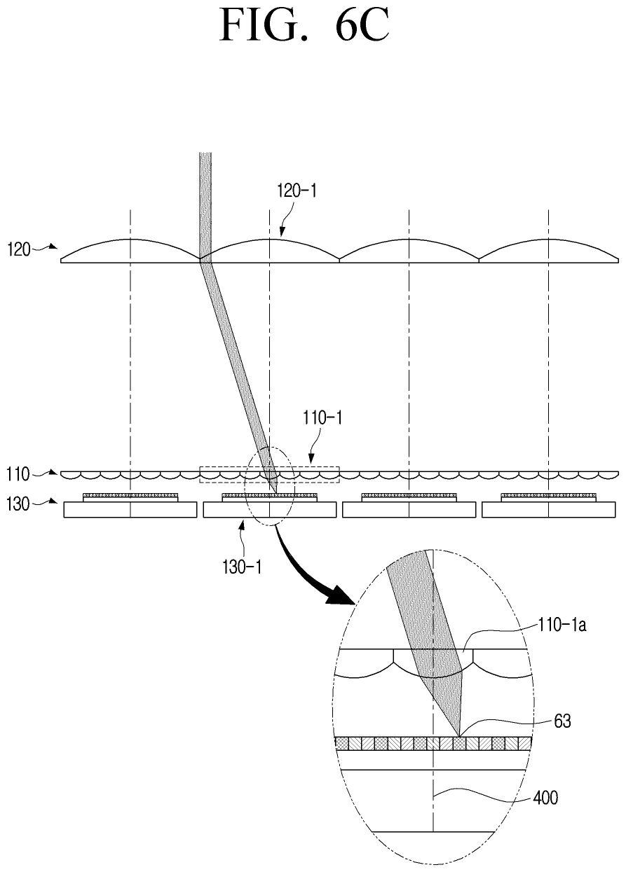

FIG. 6A is a view illustrating a path of light output from a micro-LED disposed on a side opposite to an optical axis of a plurality of second lenses from among a plurality of micro-LEDs according to an embodiment.

The light output from a micro-LED of the plurality of micro-LEDs disposed on a side opposite to an optical axis of the plurality of second lenses 120 may be incident on and refracted by a portion of the optical axis of the plurality of first lenses 110. In addition, the light refracted by the plurality of first lenses 110 may be incident on and refracted by a portion of the optical axis portion of the plurality of second lenses 120.

Referring to FIG. 6A, the light output from a micro LED 61 disposed on a side opposite to an optical axis 400 of the second-1 lens 120-1 of a plurality of micro LEDs included in the first micro display 130-1 from among the plurality of micro displays 130 may be incident on and refracted by one lens 110-1a disposed on a side opposite to the corresponding micro LED 61 from among the number of first lenses 110-1. The refracted light may be incident on and refracted by a portion of the optical axis of the second-1 lens 120-1 disposed on a side opposite to the micro LED 61 from among the plurality of second lenses 120. Here, the one lens 110-1a disposed on a side opposite to the micro-LED 61 is disposed on a side opposite to the optical axis 400 of the second-1 lens 120-1.

FIG. 6B is a view illustrating a path of light output from a micro-LED disposed on a left side of a side opposite to an optical axis of a plurality of second lenses from among a plurality of micro-LEDs according to an embodiment.

The light output from a micro-LED disposed on the left side of a side opposite to the optical axis of the plurality of second lenses 120 from among the plurality of micro-LEDs may be incident on and refracted by the plurality of first lenses 110. In addition, the light refracted by the plurality of first lenses 110 may be incident on and refracted by the plurality of second lenses 120.

Referring to FIG. 6B, the light output from a micro-LED 62 disposed on the left side of a side opposite to the optical axis 400 of the second-1 lens 120-1 from among the plurality of micro-LEDs included in the first microdisplay 130-1 from among the plurality of microdisplays 130 may be incident on and refracted by one lens 110-1a disposed on a side opposite to the corresponding micro-LED from among the number of first lenses 110-1. The refracted light may be incident on and refracted by the second-1 lens 120-1 disposed on a side opposite to the micro-LED 62 from among the plurality of second lenses 120. Here, the one lens 110-1a disposed on a side opposite to the micro-LED 62 is disposed on a side opposite to the optical axis 400 of the second-1 lens 120-1.

FIG. 6C is a view illustrating a path of light output from a micro-LED disposed on a right side of a side opposite to an optical axis of a plurality of second lenses from among a plurality of micro-LEDs according to an embodiment.

The light output from a micro-LED disposed on the right side of the plurality of micro-LEDs on a side opposite to the optical axis of the plurality of second lenses 120 from among the plurality of micro-LEDs may be incident on and refracted by the plurality of first lenses 110. In addition, the light refracted by the plurality of first lenses 110 may be incident on and refracted by the plurality of second lenses 120.

Referring to FIG. 6C, the light output from a micro-LED 63 disposed on a side opposite to the optical axis 400 of a second-1 lens 120-1 from among a plurality of micro-LEDs included in the first microdisplay 130-1 from among the plurality of microdisplays 130 may be incident on and refracted by one lens 110-1a disposed on a side opposite to the corresponding micro-LED from among the number of first lenses 110-1. The refracted light may be incident on and refracted by a second-1 lens 120-1 disposed on a side opposite to the micro-LED 63 from among the plurality of second lenses 120. Here, one lens 110-1a disposed on a side opposite to the micro-LED 63 is disposed on a side opposite to the optical axis 400 of the second-1 lens 120-1.

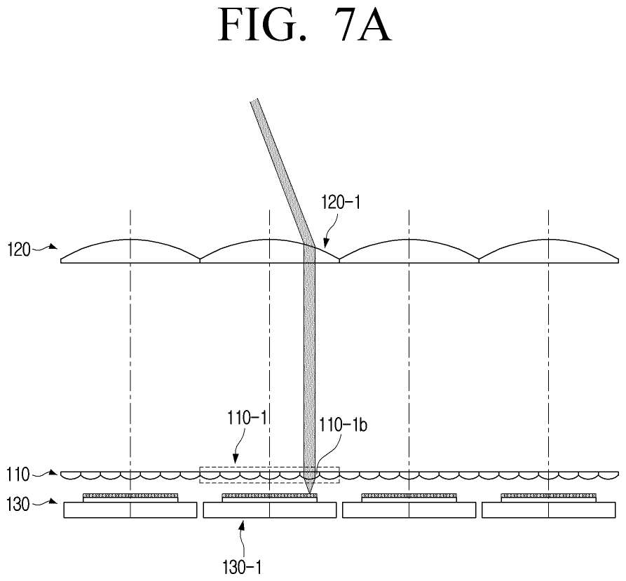

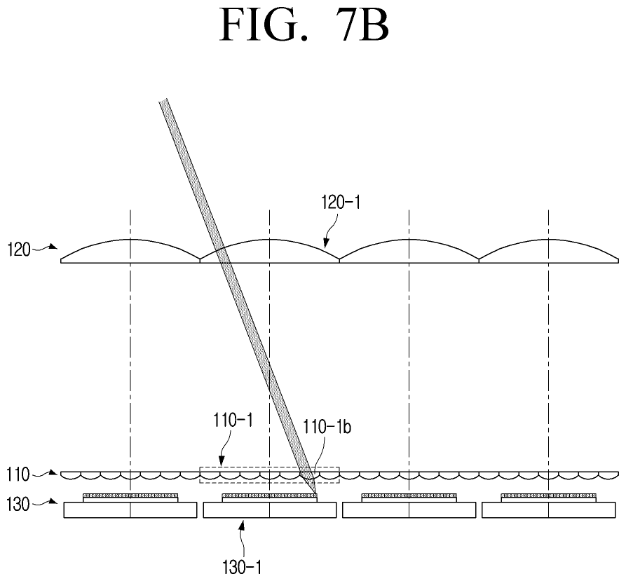

FIG. 7A is a view illustrating a path of light output from a micro-LED disposed on a right side of an optical axis of a plurality of second lenses from among a plurality of micro-LEDs according to an embodiment.

The light output from any one micro-LED disposed on the right side of the optical axis of the plurality of second lenses 120 from among the plurality of micro-LEDs may be incident on and refracted by any one lens disposed on the right side of the optical axis of the plurality of second lenses 120 from among the plurality of first lenses 110. The refracted light may be incident on and refracted by the plurality of second lenses 120.

Referring to FIG. 7A, the light output from any one micro-LED disposed on the right side of the optical axis of the second-1 lens 120-1 from among the plurality of micro-LEDs included in the first microdisplay 130-1 from among the plurality of microdisplays 130 may be incident on and refracted by any one lens 110-1b disposed on the right side of the optical axis of the plurality of second lens 120 from among the number of first lenses 110-1. The refracted light may be incident on and refracted by the second-1 lens 120-1 disposed on a side opposite to the one lens 110-1b from among the plurality of second lenses 120. Here, the one lens 110-1b is disposed on a side opposite to the second-1 lens 120-1. In addition, the one micro-LED disposed on the right side of the optical axis of the second-1 lens 120-1 in FIG. 7A is disposed on the optical axis of the one lens 110-1b.

FIG. 7B is a view illustrating a path of light output from a micro-LED disposed on a right side of an optical axis of a plurality of second lenses from among a plurality of micro-LEDs according to an embodiment.

The light output from any one micro-LEDs disposed on the right side of the optical axis of the plurality of second lenses 120 from among the plurality of micro-LEDs may be incident on and refracted by any one lens disposed on the right side of the optical axis of the plurality of second lenses 120 from among the plurality of first lenses. The refracted light may then be incident on and refracted by the plurality of second lenses 120.

Referring to FIG. 7B, the light output from any one micro-LED disposed on the right side of the optical axis of the second-1 lens 120-1 from among the plurality of micro-LEDs included in a first microdisplay 130-1 from among the plurality of microdisplays 130 may be incident on and refracted by any one lens 110-1b disposed on the right side of the optical axis of second the plurality of second lenses 120 from among the number of first lenses 110-1. The refracted light may be incident on and refracted by the second-1 lens 120-1 disposed on a side opposite to the lens 110-1b from among the plurality of second lenses 120. Here, the one lens 110-1b is disposed on a side opposite to the second-1 lens 120-1. In addition, the one micro LED disposed on the right side of the optical axis of the second-1 lens 120-1 in FIG. 7B is disposed on the right side of the optical axis of the one lens 110-1b.

FIG. 8 is a view illustrating an embodiment in which a plurality of first lenses 110 include a plurality of optical apertures according to an embodiment.

Referring to FIG. 8, the plurality of optical apertures 111 may be disposed on the plurality of first lenses 110 of the light field display 100. The plurality of optical apertures 111 may be disposed on a side opposite to a convex side of the plurality of first lenses 110.

The area where the plurality of optical apertures 111 overlap the opposite side of each of the plurality of first lenses 110 may be based on a preset ratio of the size of one of the plurality of first lenses 110. For example, the preset ratio may be 30%, in which case the optical aperture 111 may be disposed on a peripheral portion of the opposite side of one of the plurality of first lenses 110 (on a 15% region of the peripheral portion of the opposite side), as shown in FIG. 8.

As shown in FIG. 8, the optical aperture 111 may be disposed on an opposite side of the convex side of the plurality of first lenses 110 such that the light output from a micro-LED that is not disposed on a side opposite to a lens of one of the plurality of first lenses 110 is not incident on the corresponding one lens.

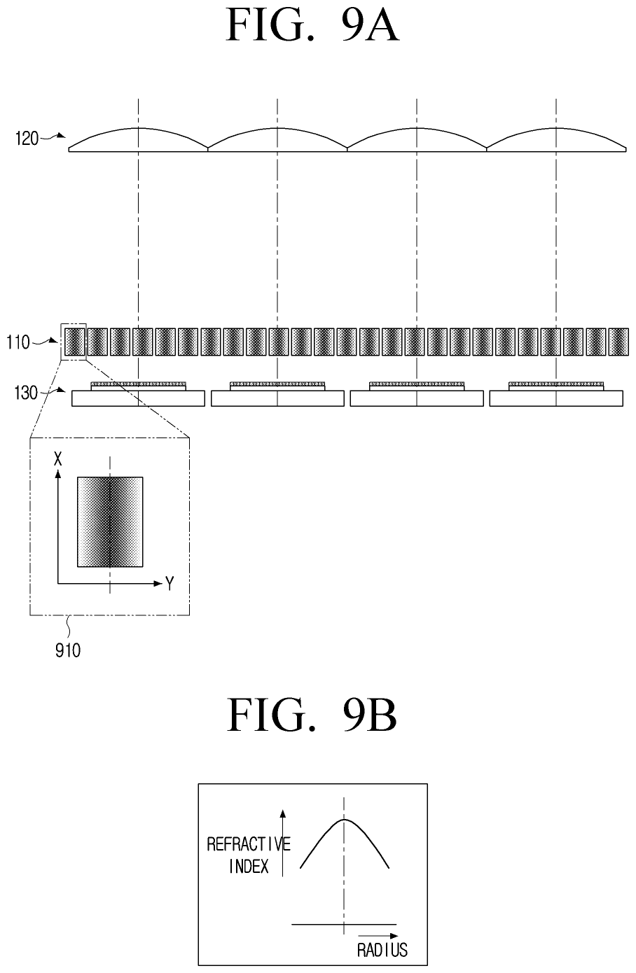

FIGS. 9A and 9B are views illustrating a case in which a plurality of first lenses are implemented as Grin lenses according to an embodiment.

Referring to FIGS. 9A and 9B, each of the plurality of first lenses 110 may be implemented as a Grin lens, which is a refractive index distribution.

A Grin lens is a gradient index (Grin) lens fabricated from an inhomogeneous medium whose refractive index varies continuously with position. In one example, a Grin lens can be fabricated using at least one of a glass or a polymer.

Referring to the 910 of FIG. 9A, and to FIG. 9B, a Grin lens according to an embodiment may have a refractive index distribution in a direction X perpendicular to the optical axis direction Y of the plurality of second lenses 120. In other words, referring to FIG. 9B, the vertical axis of FIG. 9B indicates the refractive index, and the horizontal axis indicates the radius of the Grin lens.

The Grin lens may be configured to have a large refractive index in the central portion of the Grin lens and a small refractive index in the peripheral portion. In other words, the refractive index of a Grin lens according to an embodiment may have a distribution that is maximum at the center and decreases radially.

FIG. 10 is a view illustrating a case in which one of resin or glass is disposed between a plurality of first lenses and a plurality of second lenses according to an embodiment.

In one embodiment, the space between the plurality of first lenses 110 and the plurality of second lenses 120 of the light field display 100 may be implemented as an empty space, but is not limited thereto.

Referring to FIG. 10, one 140 of resin or glass may be disposed between the plurality of first lenses 110 and the plurality of second lenses 120, such that the plurality of first lenses 110, the plurality of second lenses 120, and one 140 of resin or glass may be integrally implemented.

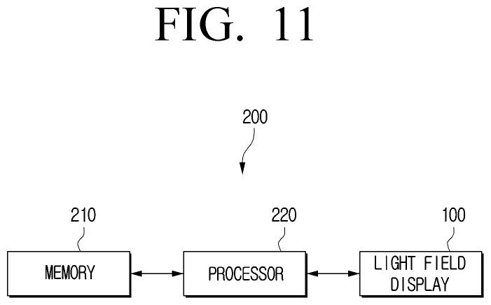

FIG. 11 is a block diagram illustrating a light field display device including a light field display according to an embodiment.

Referring to FIG. 11, a light field display device 200 may include a memory 210, a light field display 100, and a processor 220. The light field display device 200 according to an embodiment is configured to provide a 3D image through the light field display 100, and the processor 220 may control the light field display 100 to display an image for the light field display on the light field display 100.

Here, the image for the light field display may be an image that can be presented as a 3D stereoscopic image through the light field display 100. In one example, the image for the light field display may be generated based on a plurality of images taken from different viewpoints of at least one object through a light field (LF) camera. In one example, a set of the plurality of images acquired through a LF camera may be converted into an image for the light field display based on a factorization technique. In one example, the factorization technique may be implemented through a neural network model of one of a deep neural network (DNN) model, a non-negative tensor factorization (NTF) model, and a non-negative matrix factorization (NMF) model.

The memory 210 may store various programs and data required for operations of the light field display device 200. Specifically, memory 210 may store at least one instruction. The processor 220 may execute the instructions stored in the memory 210 to perform operations of the light field display device 200.

The memory 210 may store instructions or data related to at least one other component of the light field display device 200. Memory 210 may be implemented as non-volatile memory, volatile memory, flash-memory, hard disk drive (HDD), or solid state drive (SSD), or the like. The memory 210 may be accessed by the processor 220, and the data may be read/written/modified/deleted/updated by the processor 220. In this disclosure, the term “memory” may include memory 210, ROM, RAM (not shown) in the processor 220, or memory card (e.g., micro SD card, memory stick) mounted in light field display device 200.

The light field display 100 may include a plurality of first lenses 110, a plurality of second lenses 120, and a plurality of microdisplays 130, as shown in FIG. 1.

The plurality of first lenses 110 are disposed on the plurality of microdisplays 130, and may refract light output from the plurality of microdisplays 130.

The plurality of second lenses 120 are disposed on the plurality of first lenses 110, and may refract light that is refracted and projected from the plurality of first lenses 110.

The plurality of microdisplays 130 may include a plurality of microdisplays. Each of the microdisplays may include a light emitting region 131 including a plurality of micro light emitting diodes (LEDs) and a bezel region 132 surrounding the light emitting region.

The processor 220 may be electrically coupled to the memory 210 to control the overall operations and functions of the light field display device 200.

The processor 220 may include one or a plurality of processors. The one or a plurality of processors may be a general purpose processor, such as a central processing unit (CPU), an application processor (AP), etc., e a graphics-only processor, such as a GPU, a visual processing unit (VPU), etc., or an artificial intelligence-only processor, such as a neural processing unit (NPU).

The processor 220 may control the light field display 100 to display a 3D stereoscopic image using various programs (or instructions) stored in the memory 210. The processor 220 may control a plurality of microdisplays 130 within the light field display 100 to display images for the light field display. Then, the light output from the plurality of microdisplays 130 may be refracted by the plurality of first lenses 110 and the plurality of second lenses 120 to provide a 3D stereoscopic image to a viewer.

According to one or more embodiments, as described above, a light field display of the present disclosure may reduce an effect by a bezel region of microdisplays when providing an image.

The above-described embodiments are merely specific examples to describe technical content according to the embodiments of the disclosure and help the understanding of the embodiments of the disclosure, not intended to limit the scope of the embodiments of the disclosure. Accordingly, the scope of various embodiments of the disclosure should be interpreted as encompassing all modifications or variations derived based on the technical spirit of various embodiments of the disclosure in addition to the embodiments disclosed herein.

In the disclosure, the expressions “A or B”, “at least one of A or/and B”, or “one or more of A or/and B”, and the like may include any and all combinations of one or more of the items listed together. For example, the term “A or B”, “at least one of A and B”, or “at least one of A or B” may refer to all of the case (1) where at least one A is included, the case (2) where at least one B is included, or the case (3) where both of at least one A and at least one B are included. Expressions “first”, “second”, and the like, used in the disclosure may indicate various components regardless of the sequence or importance of the components. These expressions are used only to distinguish one component from another component, and do not limit the corresponding components.

When it is described that an element (e.g., a first element) is referred to as being “(operatively or communicatively) coupled with/to” or “connected to” another element (e.g., a second element), it should be understood that it may be directly coupled with/to or connected to the other element or an intervening element (e.g., a third element) may be present. In contrast, when an element (e.g., a first element) is referred to as being “directly coupled with/to” or “directly connected to” another element (e.g., a second element), it should be understood that there are no intervening elements (e.g., a third element).

An expression “˜configured (or set) to” used in the disclosure may be replaced by an expression, for example, “suitable for,” “having the capacity to,” “˜designed to,” “˜adapted to,” “˜made to,” or “˜capable of” depending on a situation. A term “˜configured (or set) to” may not necessarily mean “specifically designed to” in hardware. Instead, an expression “˜an apparatus configured to” may mean that the apparatus “is capable of” together with other apparatuses or components. For example, a “processor configured (or set) to perform A, B, and C” may mean a dedicated processor (e.g., an embedded processor) for performing the corresponding operations or a generic-purpose processor (e.g., a central processing unit (CPU) or an application processor) that may perform the corresponding operations by executing one or more software programs stored in a memory apparatus.

Meanwhile, terms “˜er/or” or “module” used in the disclosure may include units configured by hardware, software, or firmware, and may be used compatibly with terms such as, for example, logics, logic blocks, components, circuits, or the like. The “˜er/or” or “module” may be an integrally configured component or a minimum unit performing one or more functions or a part thereof. For example, the module may be configured by an application-specific integrated circuit (ASIC).

The components (e.g., modules or programs) according to various embodiments described above may include a single entity or a plurality of entities, and some of the corresponding sub-components described above may be omitted or other sub-components may be further included in the various embodiments. Alternatively or additionally, some components (e.g., modules or programs) may be integrated into one entity and perform the same or similar functions performed by each corresponding component prior to integration. Operations performed by the modules, the programs, or the other components according to the diverse embodiments may be executed in a sequential manner, a parallel manner, an iterative manner, or a heuristic manner, at least some of the operations may be performed in a different order or be omitted, or other operations may be added.

What is claimed is:

1. A light field display comprising:
a plurality of microdisplays;
a plurality of first lenses on the plurality of microdisplays and configured to refract light output from the plurality of microdisplays; and
a plurality of second lenses on the plurality of first lenses and configured to refract light that is projected from the plurality of first lenses,
wherein each of the plurality of microdisplays comprises a light emitting region comprising a plurality of micro-LEDs and a bezel region surrounding the light emitting region, and
wherein a pitch of the plurality of second lenses is greater than a pitch of the plurality of first lenses.

2. The light field display according to claim 1, wherein the pitch of the plurality of second lenses is equal to a size of one of the plurality of second lenses, and
wherein a size of one of the plurality of microdisplays is equal to the size of the one of the plurality of second lenses.

3. The light field display according to claim 1, wherein a convex side of the plurality of first lenses faces the plurality of microdisplays, and
wherein a plurality of optical apertures are provided on a side opposite to the convex side of the plurality of first lenses.

4. The light field display according to claim 3, wherein an area in which the plurality of optical apertures overlap each of the plurality of first lenses is based on a preset ratio of a size of the each of the plurality of first lenses, and
wherein the preset ratio is 30%.

5. The light field display according to claim 1, wherein each of the plurality of first lenses comprises a Grin lens with refractive index distribution.

6. The light field display according to claim 1, wherein a first microdisplay among the plurality of microdisplays corresponds to a number of first lenses among the plurality of first lenses, and
wherein the number of first lenses corresponds to a second lens among the plurality of second lenses.

7. The light field display according to claim 6, wherein one first lens among the number of first lenses corresponds to a plurality of first micro-LEDs of the first microdisplay and is configured to refract light output from the plurality of first micro-LEDs of the first microdisplay, and
wherein the second lens is configured to refract the light refracted by the one first lens among the number of first lenses.

8. The light field display according to claim 6, wherein the second lens has a size greater than a size of one first lens among the number of first lenses.

9. The light field display according to claim 6, wherein a distance between the plurality of first lenses and the plurality of second lenses is based on a quantity of first lenses included in the number of first lenses.

10. The light field display according to claim 1, further comprising a resin is between the plurality of first lenses and the plurality of second lenses.

11. The light field display according to claim 1, further comprising a glass is between the plurality of first lenses and the plurality of second lenses.

12. The light field display according to claim 1, wherein a ratio of a focal length of the plurality of first lenses and a focal length of the plurality of second lenses is within a preset range ratio, and
wherein the preset range ratio is from 20 to 200.

13. The light field display according to claim 1, wherein the plurality of second lenses is configured to refract the light output from the plurality of microdisplays and provide a stereoscopic image.

14. A light field display device comprising;
a light field display;
a memory including at least one instruction; and
a processor connected to the memory and configured to control the light field display by executing the at least one instruction,
wherein the light field display comprises:
a plurality of microdisplays;
a plurality of first lenses on the plurality of microdisplays and configured to refract light output from the plurality of microdisplays; and
a plurality of second lenses on the plurality of first lenses and configured to refract light that is projected from the plurality of first lenses,
wherein each of the plurality of microdisplays comprises a light emitting region comprising a plurality of micro-LEDs and a bezel region surrounding the light emitting region, and
wherein a pitch of the plurality of second lenses is greater than a pitch of the plurality of first lenses.
